(19) United States
(12) Patent Application Publication
(10) Pub. No.: US 2024/0363358 A1
(43) Pub. Date: Oct. 31, 2024

(54) METHODS FOR CHEMICALLY ETCHING A TARGET LAYER

(71) Applicant: ASM IP Holding B.V., Almere (NL)

(72) Inventors: Timothee Blanquart, Oud-Heverlee (BE); Charles Dezelah, Helsinki (FI); René Henricus Jozef Vervuurt, Leuven (BE)

(21) Appl. No.: 18/647,931

(22) Filed: Apr. 26, 2024

Related U.S. Application Data
(60) Provisional application No. 63/462,552, filed on Apr. 28, 2023.

(51) Int. Cl. H01L 21/311; H01L 21/02

(52) U.S. Cl. CPC H01L 21/31122; H01L 21/02321; H01L 21/02337

(57) ABSTRACT

Methods for chemically etching a target layer are disclosed. In particular, methods for etching a target layer by cyclical chemical vapor etching processes and atomic layer etching processes are disclosed. Exemplary apparatus for performing chemical etching processes are further disclosed.

### CROSS-REFERENCE TO RELATED APPLICATION(S)

This Application claims the benefit of U.S. Provisional Application 63/462,552 filed on Apr. 28, 2023, the entire contents of which are incorporated herein by reference.

### FIELD OF INVENTION

The present disclosure generally relates to the field of semiconductor processing methods, and to the field of device and integrated circuit manufacture. More particularly, the present disclosure relates to methods for chemically etching a target layer.

### BACKGROUND OF THE DISCLOSURE

The manufacture of semiconductor devices relies on the precise formation of material layers with controlled thicknesses and surface topographies. To obtain such particular layers, etching of selected materials, and/or portions thereof, may be performed. Etch processes for removing portions of a desired material layer, also referred to herein as a target layer, can commonly be categorized as either wet-etch processes or dry-etch processes.

As the name suggests, wet-etch processes employ liquid etchants, wherein a target layer is immersed in, or otherwise contacted with, a corrosive liquid which can isotropically etch the target layer equally in all directions simultaneously. Although wet-etch processes can rapidly remove material using relatively simple equipment, such processes tend to be difficult to control, both in terms of the etch rate and the end point, but can also be limited when etch directionality (i.e., isotropic vs anisotropic) of the target layer is desired.

In contrast, dry-etch methods generally employ gaseous reactants in either a plasma state or a non-plasma state. Plasma based etch processes commonly utilize a gas energized into an excited plasma state to produce reactive species which can be directed to and etch the target layer. However, common plasma based etch processes, such as reactive ion etching, can lack the required etch selectivity and precision especially when the amount of material to be removed from the target layer is in the nanometer scale and below. In addition, the high energy reactive species produced within the plasma can have detrimental effects on the unetched portions of the target layer and/or those layers proximate to the target layer.

In non-plasma etch methods, vapor phase chemistries are commonly used that react with the surface of a target layer to produce gaseous reaction products in a plasma free environment. The reaction products are removed from the substrate surface, leading to etching of the target layer in question. Vapor phase etching methods such as chemical vapor etching (CVE) and atomic layer etching (ALEt) have received increasing attention in recent years due to a wide variety of potential applications in the semiconductor industry. However, such chemical etching processes can lack specificity to certain target materials and therefore there is a need for improved chemical etch processes.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

In particular the present disclosure includes methods for chemically etching a target layer, the methods comprising, seating a substrate comprising a target layer in a reaction chamber, and contacting a surface of the target layer with an etch-priming reactant comprising a haloalkylamine thereby forming a modified surface, and contacting the modified surface with an etchant comprising a halogenated silane thereby etching a portion of the target layer.

In some embodiments, the target layer comprises a transition metal oxide.

In some embodiments, the transition metal oxide comprises a ternary transition metal oxide.

In some embodiments, the ternary transition metal oxide comprises a hafnium zirconium oxide.

In some embodiments, the etch-priming reactant and the etchant are introduced into the reaction chamber alternately and sequentially.

In some embodiments, the haloalkylamine comprises a carbon atom bonded to a nitrogen atom and to at least one fluorine atom.

In some embodiments, the haloalkylamine is selected from the group consisting of 2,2-difluoro-1,3-dimethylimidazolidine, N,N-diethyl-1,1,2,3,3,3-hexafluoro-1-propanamine, and 1,1,2,2,-tetrafluoroethyl-N,N-dimethylamine.

In some embodiments, the halogenated silane comprises an iodosilane selected from the group consisting of iodosilane (H₃Sil), diiodosilane (H₂Sil₂), tetraiododisilane (H₂Si₂I₄), and triiodosilane (HSil₃).

In some embodiments, the halogenated silane comprises tetraiododisilane (H₂Si₂I₄).

In some embodiments, the methods of the present disclosure further include heating the substrate to a temperature of less than 400° C.

The present disclosure also includes further methods for chemically etching a transition metal target layer, such method comprising, seating a substrate comprising a transition metal oxide target layer in a reaction chamber, and performing a cyclical etch process comprising one or more repeated etch cycles, wherein a unit etch cycle of the cyclical etch process comprises, contacting the transition metal oxide target layer with a vapor phase fluoroalkylamine thereby forming a fluorinated transition metal oxide surface, and contacting the fluorinated transition metal oxide surface with a vapor phase halogenated silane etchant.

In some embodiments, the vapor phase fluoroalkylamine is selected from the group consisting of 2,2-difluoro-1,3-dimethylimidazolidine, N,N-diethyl-1,1,2,3,3,3-hexafluoro-1-propanamine, and 1,1,2,2,-tetrafluoroethyl-N,N-dimethylamine.

In some embodiments, the halogenated silane etchant comprises diiodosilane.

In some embodiments, the transition metal oxide layer comprises a hafnium zirconium oxide layer.

In some embodiments, the hafnium zirconium oxide layer is crystalline.

In some embodiments, the cyclical etch process is performed in a plasma-free environment.

The present disclosure also includes methods for atomic layer etching a hafnium zirconium oxide layer, the method comprising, seating a substrate comprising a hafnium zirconium oxide layer into a reaction chamber, and performing an atomic layer etching process comprising a plurality of repeated etch cycles, wherein a unit etch cycle of the atomic layer etch process comprises, contacting a surface of the hafnium zirconium oxide layer with a vapor phase fluorinating agent comprising a carbon atom bonded to a nitrogen atom and to at least one fluorine atom thereby forming a fluorinated hafnium zirconium oxide surface, contacting the fluorinated hafnium zirconium oxide surface with a vapor phase iodosilane etchant thereby etching no more than a monolayer of the metal oxide layer.

The present disclosure further includes methods for chemically etching a target layer, the methods comprising, seating a substrate comprising a target layer in a reaction chamber, and contacting a surface of the target layer with an etch-priming reactant comprising a haloalkylamine thereby forming a modified surface, and contacting the modified surface with an etchant comprising a metalorganic compound having a group 4 metal bonded to an alkylamine group thereby etching a portion of the target layer. In some embodiments, the group 4 metal is selected from titanium, hafnium and zirconium. In some embodiments, the group 4 metal is titanium. In some embodiments, the group 4 metal is hafnium. In some embodiments, the group 4 metal is zirconium.

The present disclosure further includes methods for chemically etching a transition metal target layer. These methods comprise seating a substrate comprising a transition metal oxide target layer in a reaction chamber and performing a cyclical etch process comprising one or more repeated etch cycles, wherein a unit etch cycle of the cyclical etch process comprises contacting the transition metal oxide target layer with a vapor phase fluoroalkylamine thereby forming a fluorinated transition metal oxide surface; and contacting the fluorinated transition metal oxide surface with a vapor phase etchant comprising a metalorganic compound having a group 4 metal bonded to an alkylamine group.

The present disclosure further includes methods for atomic layer etching a hafnium zirconium oxide layer. The methods comprising seating a substrate comprising a hafnium zirconium oxide layer into a reaction chamber; and performing an atomic layer etching process comprising a plurality of repeated etch cycles. A unit etch cycle of the atomic layer etch process comprises contacting a surface of the hafnium zirconium oxide layer with a vapor phase fluorinating agent comprising a carbon atom bonded to a nitrogen atom and to at least one fluorine atom thereby forming a fluorinated hafnium zirconium oxide surface, contacting the fluorinated hafnium zirconium oxide surface with a vapor phase etchant comprising a metalorganic compound having a group 4 metal bonded to an alkylamine group thereby etching a portion of the target layer. In some embodiments, the atomic layer etching process is performed in a plasma-free environment.

In some embodiments, the hafnium zirconium oxide layer comprises a crystalline hafnium zirconium oxide layer.

The present disclosure also includes apparatus for performing the etching methods disclosure herein.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates an exemplary method according to the embodiments of the present disclosure; and

FIG. 2 illustrates an exemplary semiconductor processing apparatus according to the embodiments of the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the present disclosure provide methods for chemically etching a target layer. In particular, the embodiments of the disclosure relate to chemical vapor etching processes including, but not limited to, cyclical chemical vapor etching processes, and atomic layer etching processes. Exemplary etching methods of the present disclosure can be used for the precise etching of a target layer comprising a metal oxide, and particular a ternary metal oxide film, such as, a hafnium zirconium oxide, for example. However, unless noted otherwise, the invention is not necessarily limited to such examples.

As used herein, the term “gas” can include material that is a gas at normal temperature and pressure (NTP), a vaporized solid and/or a vaporized liquid, and can be constituted by a single gas or a mixture of gases, depending on the context. A reactant may be provided to the reaction chamber in the gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. The substrate can include various topologies, such as gaps, including recesses, lines, trenches or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “film” and/or “layer” can refer to any continuous or non-continuous structure and material. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, the term “target layer” can refer to a layer of material that is etchable by the processes and chemistries of the present disclosure. For example, a “target layer” is a layer of material with a composition which is capable of being etched by the methods and chemistries disclosed herein.

As used herein, the term “etch-priming reactant” can refer to a reactant that interacts with a surface of the target layer and in doing so modifies particular properties of the surface of the target layer. For example, an etch-priming reactant can modify one or more of the physical and chemical properties of a surface of the target layer.

As used herein, the term “modified surface” can refer to a surface of a layer of material, such as a surface of a target layer, which has been modified from its original unmodified state by the interaction between the original unmodified surface and an etch-priming reactant. For example, an etch-priming reactant may contact and modify a surface of a target layer to form a modified surface which has a surface chemistry which is different from that of the original unmodified surface.

As used herein, the term “fluorinated surface” can refer to a surface of a layer of material, such a surface of target layer, which has been modified from its original unmodified state, e.g., via contact with an etch-priming reactant, to form a modified surface comprising fluorine species. As a non-limiting example, a surface of a target layer may be modified to form a “fluorinated surface” by contacting a surface of the target with a “fluorinating agent”, wherein the fluorinating agent comprises a reactant including one of more fluorine atoms.

As used herein, the term “haloalkylamine” can refer to a reactant that comprises a halogen component, and an alkylamine component. The halogen component can comprise one or more of fluorine, chlorine, chlorine, and bromine. The alkylamine component can comprise an amine in which an alkyl group substituent is attached to a nitrogen atom. For example, a “fluoroalkylamine” can refer to a reactant that comprise a fluorine component and an alkylamine component.

As used herein, the term “halogenated silane” (also referred to as a halosilane) can refer to a reactant, and particular an etchant, that comprise at least one silicon atom, at least one hydrogen atom, and at least one halogen atom selected from the group consisting of fluorine, chlorine, bromine, and iodine.

As used herein, the term “iodosilane” can refer to a halogenated silane reactant including at least one iodine atom.

As used herein, the term “metal oxide” can refer to a layer of material comprising a chemical compound having a chemical formula including at least one oxygen atom and a metal atom. For example, a “transition metal oxide” can refer to a layer of material comprising a chemical compound having a chemical formula including at least one oxygen atom and a transition metal atom. In addition, a “ternary transition metal oxide” can refer to a layer of material comprising a ternary chemical compound (also referred to as a ternary phase) having a chemical formula including at least one oxygen atom, a metal atom, and an additional element, such as a second metal atom.

As used herein, the term “hafnium zirconium oxide” can refer to layer of material comprising a ternary transition metal oxide having a chemical compound comprising a hafnium atom, a zirconium atom, and an oxygen atom.

The term “cyclic etch process” or “cyclical etch process” can refer to the sequential introduction of reactants into a reaction chamber to etch at least a portion of a target layer and includes processing techniques such as cyclical chemical vapor etch and atomic layer etch (ALEt). Atomic layer etching (ALEt) is a comparable technique to atomic layer deposition (ALD), in that separated pulses of one or more reactants are utilized. However, rather than depositing material as in ALD, in ALEt thin layers of material are controllably removed using sequential reaction steps. In ALEt processes the sequential reaction steps are self-limiting. In contrast to conventional continuous etching, ALEt typically utilizes one or more etching cycles to remove material.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. This notwithstanding, the chemical compound, substance, or composition of matter may, in some embodiments, comprise other components as trace elements or impurities, apart from the components that are listed.

A number of example materials are given throughout the embodiments of the current disclosure, it should be noted that the chemical formulas given for each of the example materials should not be construed as limiting and that the non-limiting example materials given should not be limited by a given example stoichiometry.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The embodiments of the present disclosure include methods for etching a target layer and can include cyclical chemical etch processes, such as, for example, cyclical chemical vapor etch processes and atomic layer etch processes. The etch processes of the present disclosure do not employ reactive species generated by a plasma and can therefore be referred to as “plasma-free” processes or alternatively, as purely thermal chemical vapor etch processes performed in a “plasma-free” environment. In addition, the etch processes of the present disclosure can employ etch-priming reactants to enable the modification of a surface of a target layer. Subsequently, the modified surface of the target layer can be contacted with a vapor phase etchant enabling the self-limiting removal of a portion of the target layer with atomic layer precision.

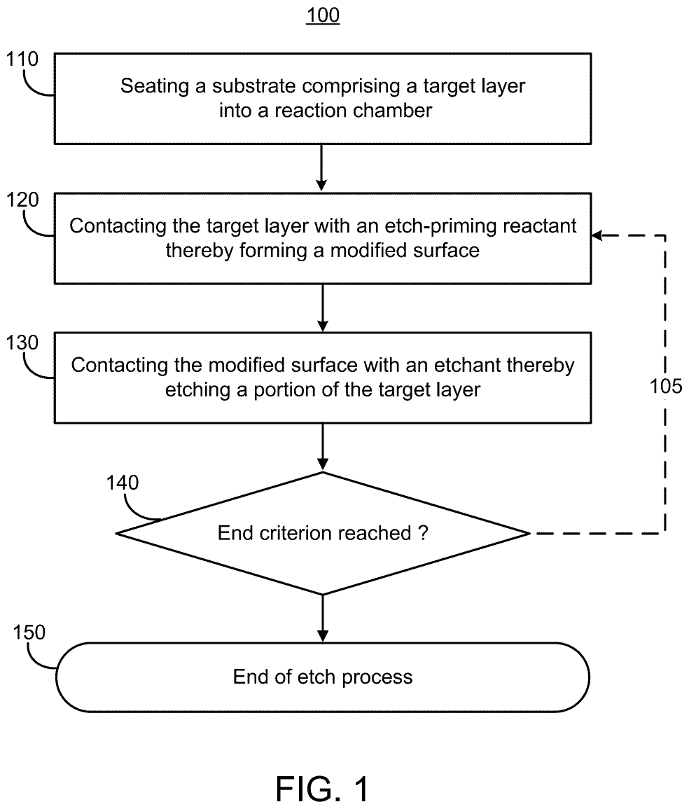

In more detail, FIG. 1 illustrates an exemplary process 100 for chemically etching a target layer according to the embodiments of the present disclosure. The exemplary process 100 may commence with a process step 110 comprising, seating a substrate comprising a target layer in a reaction chamber.

In more detail, the substrate can include one or more target layers composed of material(s) that are capable of being etched by the processes and chemistries of the present disclosure. In some embodiments, the target layer may comprise a metal oxide. In some embodiments, the target layer may comprise a transition metal oxide. In some embodiments, the target layer may comprise a ternary transition metal oxide. In some embodiments, the target layer may comprise a mixture of two or more transition metal oxides. In some embodiments, the substrate may comprise multiple target layers comprising ternary transition metal oxides with the same chemical formula and with substantially the same composition stoichiometry. In some embodiments, the substrate may comprise multiple target layers comprising ternary transition metal oxides with the same chemical formula but with different composition stoichiometry. In some embodiments, the ternary transition metal oxide is a ferroelectric material.

In some embodiments, the target layer may comprise a ternary transition metal oxide comprising hafnium zirconium oxide (HfZrO), where hafnium zirconium oxide is a material that can be represented by a chemical formulate that includes hafnium, zirconium, and oxygen, and the abbreviation HfZrO refers to a material comprising these elements, without limiting the stoichiometry of the elements. In some embodiments, hafnium zirconium oxide may not include significant proportions of elements other than hafnium, zirconium, and oxygen. In some embodiments, the hafnium zirconium oxide comprises HfZrO. In some embodiments, the hafnium zirconium oxide may consist essentially of HfZrO. A layer consisting of hafnium zirconium oxide may include an acceptable amount of impurities, such as hydrogen, carbon, chlorine, and/or the like that may originate from one or more precursors used in forming the hafnium zirconium oxide.

In some embodiments, the substrate may comprise multiple target layers comprising a hafnium zirconium oxide composed of hafnium, zirconium, and oxygen, with substantially the same composition stoichiometry. In some embodiments, the substrate may comprise multiple target layers comprising hafnium zirconium oxides composed of hafnium, zirconium, and oxygen with differing composition stoichiometry. In some embodiments, the stoichiometry of the transition metal and the additional element is about 1:1. In some embodiments, the stoichiometry of the ternary metal oxide is about AₓB_{y}O₂, wherein A is a transition metal, B is additional element, O is oxygen, and x+y=1. In some embodiments, the atomic proportions of the elements are about A_{0.5}B_{0.5}O₂, such as Hf_{0.5}Zr_{0.5}O₂.

In some embodiments, the target layer comprises a crystalline hafnium zirconium oxide in which the crystalline structure of the hafnium zirconium oxide exhibits long range ordering. It should be appreciated that a crystalline hafnium zirconium oxide may not be a perfect single crystal but may also comprise various defects, stacking faults, atomic substitutions, and the like, as long as the crystalline material exhibits long range ordering.

In some embodiments, the substrate may comprise one or more secondary layers in addition to the target layer, where the secondary layers comprise materials different to that of the target layer. In some embodiments, the substrate may comprise at least two layers, a target layer and a secondary layer, the secondary layer having a different composition to the target layer. For example, the chemical etching processes of the present disclosure may selectively etch the target layer relative to the secondary layer. In some embodiments, the substrate may comprise secondary layers including oxides (different in composition to the target layer) as well as, nitrides, carbides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials.

In some embodiments of the current disclosure, the substrate comprises silicon. In some embodiments, the substrate may comprise other material in addition to silicon, such as those described above.

The process step 110 of exemplary process 100 also comprises, seating the substrate in a reaction chamber. The reaction chamber may be configured for performing all, or a portion, of the remaining process steps of exemplary process 100. Reactors and associated reaction chamber(s) capable of the chemical etching processes according to the embodiments of the present disclosure may include reaction chambers configured to perform cyclical chemical etch processes, such as, for example reaction chambers configured to perform cyclical chemical vapor etching and atomic layer etching, as well as reaction chambers configured for the introduction of reactants in a cyclical manner. For example, in some embodiments, the chemical etch process of the present disclosure may be performed within a semiconductor processing apparatus configured for atomic layer deposition as well as atomic layer etching and cyclical chemical vapor etching.

In some embodiments, the reaction chamber employed for chemical etching process can be, or include, a reaction chamber of an atomic layer deposition reactor system configured to perform one or more cyclical etch process. The reaction chamber can be a standalone reaction chamber or part of a cluster tool. The reaction chamber may be a batch processing tool. In some embodiments, a flow-type reactor may be utilized. In some embodiments, a showerhead-type reactor may be utilized. In some embodiments, a space divided reactor may be utilized. In some embodiments, a high-volume manufacturing-capable single wafer reactor may be utilized. In other embodiments, a batch reactor comprising multiple substrates may be utilized. For embodiments in which a batch reactor is used, the number of substrates may be in the range of 10 to 200, or 50 to 150, or even 100 to 130. The reactor can be configured as a thermal reactor—with no plasma excitation apparatus.

Once the substrate is seated within the reaction chamber the substrate can be heated to a suitable substrate temperature for performing the chemical etching processes of the present disclosure. In some embodiments, the substrate is heated to a substrate temperature of less than 400° C., or less than 300° C., or less than 250° C., or less than 200° C., or less than 150° C., or less than 100° C., or less than 50° C., or between 50° C. and 400° C. In some embodiments, a chemical etching process according to the current disclosure can be performed at an ambient temperature. The ambient temperature may be, for example from about 20° C. to about 30° C.

In addition to controlling the temperature of the substrate, the methods of the present disclosure may be performed in reduced pressure. In some embodiments, a pressure within the reaction chamber can be between about 1 mTorr and about 760 Torr, or about 0.5 Torr and about 30 Torr, such as about 10 Torr, about 15 Torr or about 20 Torr. In some embodiments, a pressure within the reaction chamber during the etch process according to the current disclosure is less than 500 Torr, or a pressure within the reaction chamber during the etch process is between 0.1 Torr and 500 Torr, or between 1 Torr and 100 Torr, or between 1 Torr and 20 Torr. In some embodiments, a pressure within the reaction chamber during the etch process is less than about 10 Torr, less than 50 Torr, less than 100 Torr or less than 300 Torr.

Once the substrate is at the desired process temperature and the pressure in the reaction chamber has been regulated as desired, the exemplary process 100 (FIG. 1) may continue by way of a process step 120 comprising, contacting a surface of the target layer with an etch-priming reactant thereby forming a modified surface.

In more detail, an etch-priming reactant can be provided into the reaction chamber, wherein it contacts the target layer disposed therein. In the methods to the present disclosure, the etch-priming reactant may be in the vapor phase when it is within the reaction chamber. The etch-priming reactant may be partially gaseous or liquid, or even solid at some points in time prior to being provided into the reaction chamber. In other words, an etch-priming reactant may be solid, liquid or gaseous, for example, in a source vessel or other receptacle before delivery to the reaction chamber. Various means of bringing the etch-priming reactant into the gas phase can be applied when delivery the reactant into the reaction. Such means may include, for example, heaters, vaporizers, gas flow or applying lowered pressure, or any combination thereof.

Thus, the methods according to the current disclosure may comprise heating the etch-priming reactant prior to providing it to the reaction chamber. In some embodiments, the etch-priming reactant is heated to at least 30° C., or to at least 40° C., or to at least 50° C., or to at least 100° C. in a source vessel. An injector system for injecting the etch-priming reactant into a reaction chamber may be heated to improve the vapor phase delivery of the etch-priming reactant to the reaction chamber. In some embodiments, the etch-priming reactant is not heated. A suitable temperature may depend on the properties of the etch-priming reactant in question, such as temperature sensitivity and vapor pressure. In some embodiments, the process according to the current disclosure is performed at a temperature from about 20° C. to about 120° C. Thus, the temperature in a reaction chamber may be, for example, from about 20° C. to about 100° C., or from about 20° C. to about 60° C.

In some embodiments, the etch-priming reactant employed in process step 120 comprises a haloalkylamine. In some embodiments, the haloalkylamine comprises a carbon atom bonded to a nitrogen atom and to at least one fluorine atom. In some embodiments, the haloalkylamine may comprise a vapor phase fluoroalkylamine. For example, the fluoroalkylamine may be represented by a formula R-NR′₂, wherein R is a fluorinated C1 to C5 alkyl, and each R′ is independently selected from methyl, ethyl and propyl. In some embodiments, both R′ are the same. In some embodiments, R comprises at least two fluorine (F) atoms. In some embodiments, R comprises at least three fluorine (F) atoms. In some embodiments, R comprises at least four fluorine (F) atoms. In some embodiments, R comprises at least six fluorine (F) atoms. In some embodiments, R comprises two fluorine (F) atoms. In some embodiments, R comprises three fluorine (F) atoms. In some embodiments, R comprises four fluorine (F) atoms. In some embodiments, R comprises six fluorine (F) atoms. In some embodiments, all of the carbon atoms in the R alkyl are fluorinated. In some embodiments, R is fully fluorinated.

In some embodiments, the fluoroalkylamine is represented by a formula (I), wherein each R1 is independently selected from methyl, ethyl and propyl. In some embodiments, both R1 are the same. In some embodiments, both R1 are methyl. In some embodiments, both R1 are ethyl. In some embodiments, both R1 are propyl.

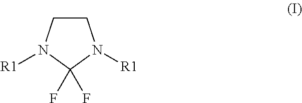

In some embodiments, the haloalkylamine is selected from the group consisting of 2,2-difluoro-1,3-dimethylimidazolidine, N,N-diethyl-1,1,2,3,3,3-hexafluoro-1-propanamine, and 1,1,2,2,-tetrafluoroethyl-N,N-dimethylamine. In some embodiments, the etch-priming reactant may comprise a vapor phase fluorinating agent. Further suitable etch-priming reactants comprising haloalkylamines are described in U.S. patent application filing Ser. No. 18/056,169, filed 16 Nov. 2022 and entitled “Etch process and a processing assembly” the entire contents of which is incorporated by reference herein.

In some embodiments, contacting the target layer with the etch-priming reactant results in a target layer with a modified surface Without limiting the current disclosure to any specific theory, the etch-priming reactant may chemisorb on a surface of the target layer upon contacting the target layer, i.e., during providing the etch-priming reactant into the reaction chamber. In addition, the chemisorption of the etch-priming reactant upon a surface of the target layer can result in a modification of the contacted surface, i.e., forming a modified surface. For example, the modified surface of the target layer can be modified from the original unmodified surface via a change in the surface chemistry of the surface of the target layer. Such a change in the surface chemistry of the target layer can result in a modified surface of the target which has an increased affinity to a subsequently introduced vapor phase etchant thereby enabling etching of the target layer.

Therefore, in some embodiments, contacting a surface of the target layer with an etch-priming reactant comprises forming a modified surface. In some embodiments, the etch-priming reactant comprises a vapor phase fluoroalkylamine and upon contact of the fluoroalkylamine with a surface of the target layer the resulting modified surface can comprise a fluorinated surface. In embodiments wherein the target layer comprises a transition metal oxide target layer the modified surface formed upon contact with a vapor phase fluoroalkylamine etch-priming reactant can comprise a fluorinated transition metal oxide surface. In embodiments wherein the target layer comprises a hafnium zirconium oxide, the modified surface formed upon contact with a vapor phase fluoroalkylamine etch-priming reactant can comprise a fluorinated hafnium zirconium oxide surface. In embodiments wherein the target layer comprises a hafnium zirconium oxide and the etch-priming reactant comprises a fluorinating agent, the modified surface formed upon contact with the fluorinating agent can comprise a fluorinated hafnium zirconium oxide surface.

The duration of providing the etch-priming reactant into the reaction chamber (etch-priming reactant pulse time) may be, for example, from about 5 seconds to about 20 minutes. The duration of providing etch-priming reactant into the reaction chamber is selected based on the process, tool and other factors. In some embodiments, the duration of providing the etch-priming reactant into the reaction chamber is from about 5 seconds to about 2 minutes, or from about 5 seconds to about 90 seconds, or from about 5 seconds to about 60 seconds. In some embodiments, the duration of providing the etch-priming reactant into the reaction chamber is from about 15 seconds to about 5 minutes, or from about 15 seconds to about 3 minutes, or from about 15 seconds to about 2 minutes, or from about 10 seconds to about 90 seconds. In some embodiments, the duration of providing the etch-priming reactant into the reaction chamber (etch-priming reactant pulse time) is longer than 5 seconds or longer than 10 seconds or longer than 30 seconds, or longer than 60 seconds. In some embodiments, the duration of providing the etch-priming reactant into the reaction chamber (etch-priming reactant pulse time) may be shorter than about 15 minutes or shorter than about 10 minutes or shorter than about 5 minutes, or shorter than about 3 minutes, or shorter than about 60 seconds, or shorter than about 30 seconds.

Upon completion of the process step 120 (FIG. 1) the reaction chamber may be purged to remove any excess etch-priming reactant and any reaction products, if present. In some embodiments, the purge time after the providing the etch-priming reactant pulse may be from about 0.1 seconds to about 120 seconds, or from about 0.1 seconds to about 60 seconds, or from about 0.1 seconds to about 30 seconds, or from about 0.1 seconds to about 10 seconds, or from about 0.1 seconds to about 5 seconds, or from about 0.1 seconds to about 2 seconds, or from about 0.1 seconds to about 1 second, or from about 0.1 seconds to about 0.5 seconds. In some embodiments, the purge time after introducing the etch-priming reactant is shorter than 60 seconds, shorter than 30 seconds, shorter than 10 seconds, shorter than 4 seconds, shorter than 1 seconds, or shorter than 0.5 seconds.

The exemplary process 100 of FIG. 1 may continue via a process step 130 which comprises, contacting the modified surface of the target layer with an etchant thereby etching a portion of the target layer. In some embodiments of the disclosure, the etchant comprises a vapor phase halogenated silane. In some embodiments, the vapor phase halogenated silane (also referred to as a halosilane) can comprise a reactant, and particular an etchant, that comprise at least one silicon atom, at least one hydrogen atom, and at least one halogen atom selected from the group consisting of fluorine (F), chlorine (Cl), bromine (Br), and iodine (I). In some embodiments, the vapor phase halogenated silane comprises a silane having a formula SiₐH_{b}X_{c}, wherein X is selected from at least one of F, Cl, Br and I; a is 1, 2 or 3, b+c=2a+2, and wherein c is at least 1. For example, in some embodiments, the vapor phase halogenated silane is a iodosilane having a formula Si₂H_{b}I_{c}. In some embodiments, the vapor phase halogenated silane is a bromosilane having a formula Si₂H_{b}Br_{c}. In some embodiments, the vapor phase halogenated silane is a chlorosilane having a formula SiₐH_{b}Cl_{c}. In some embodiments, the vapor phase halogenated silane is a fluorosilane having a formula SiₐH_{b}F_{c}. In some embodiments, the vapor phase halogenated silane comprises a disilane. In some embodiments, the vapor phase halogenated silane comprises an iodosilane selected from the group consisting of iodosilane (H₃Sil), diiiodosilane (H₂I₂Si), triiodosilane HI₃Si) and tetraiododisilane (H₂I₄Si₂). In some embodiments, the vapor phase halogenated silane comprises diiiodosilane (H₂I₂Si).

In some embodiments, process step 130 may further comprise, contacting the modified surface (e.g., of the target layer) with an etchant comprising a halogenated silane thereby etching a portion of the target layer. In some embodiments, the modified surface comprises a fluorinated transition metal oxide surface and the process step 130 comprises, contacting the fluorinated transition metal oxide surface with a vapor phase halogenated silane etchant. In some embodiments, the modified surface comprises a fluorinated hafnium zirconium oxide surface and the process step 130 comprises, contacting the fluorinated hafnium zirconium oxide surface with a vapor phase iodosilane thereby etching no more than a monolayer of the hafnium zirconium oxide target layer

In some embodiments, process step 130 may further comprise contacting the modified surface (e.g., of the target layer) with an etchant comprising a metalorganic compound having a group 4 metal bonded to an alkylamine group thereby etching a portion of the target layer. In some embodiments of the disclosure, the etchant comprises a group 4 metal selected from titanium, hafnium and zirconium. In some embodiments, the group 4 metal is titanium. In some embodiments, the group 4 metal is hafnium. In some embodiments, the group 4 metal is zirconium.

In some embodiments, the group 4 metal is bonded to one alkylamine group. In some embodiments, the group 4 metal is bonded to two alkylamine groups. In some embodiments, the group 4 metal is bonded to three alkylamine groups. In some embodiments, the group 4 metal is bonded to four alkylamine groups. In some embodiments, the group 4 metal is bonded to at least one alkylamine group. In some embodiments, the group 4 metal is bonded to at least two alkylamine groups. In some embodiments, the group 4 metal is bonded to at least three alkylamine groups.

An alkylamine group according to the current disclosure is an −N—R₂ group, in which N is a nitrogen atom bonded to the group 4 metal, each R is independently a C1 to C5 alkyl. In some embodiments, each R is independently a C1 to C4 alkyl. In some embodiments, each R is independently a C1 to C3 alkyl. In some embodiments, each R is independently a methyl or ethyl. Each alkyl group in the etchant may be linear or branched. In some embodiments, all R are the same alkyl. In some embodiments, all alkyls are methyl. In some embodiments, all alkyls are ethyl. In some embodiments, all alkyls are propyl (selected independently of n-propyl and isopropyl). In some embodiments, all alkyls are butyl (selected independently from n-butyl, isobutyl, sec-butyl and tert-butyl).

In some embodiments, the etchant according to the current disclosure has a formula M (NR₂)₄, wherein M is selected from Ti, Hf and Zr, each R is independently selected from methyl, ethyl, n-propyl, isopropyl, n-butyl, isobutyl, sec-butyl, tert-butyl, n-pentyl, 1,1-dimethylpropyl, 3-methylbutyl, 1-methylbutyl, 2,2-dimethylpropyl, 1-ethylpropyl, 1,2-dimethylpropyl, 2-methylbutyl, n-hexyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 3,3-dimethylbutyl, 1-ethylbutyl and 2-ethylbutyl. In some embodiments, the etchant according to the current disclosure is selected from a group consisting of tetrakis (dimethylamino) titanium, tetrakis (dimethylamino) hafnium and tetrakis (dimethylamino) zirconium.

In some embodiments, the process according to the current disclosure is a cyclic etching process, and comprises providing N,N-diethyl-1,1,2,3,3,3-hexafluoropropylamine and tetrakis (dimethylamino) titanium alternately and sequentially into the reaction chamber. In some embodiments, the process according to the current disclosure is a cyclic etching process, and comprises providing 1,1,2,2-tetrafluoro-N,N-dimethylethanamine and tetrakis (dimethylamino) titanium alternately and sequentially into the reaction chamber. In some embodiments, the process according to the current disclosure is a cyclic etching process, and comprises providing 2,2-difluoro-1,3-dimethylimidazolidine and tetrakis (dimethylamino) titanium alternately and sequentially into the reaction chamber. In some embodiments, the process according to the current disclosure is a cyclic etching process, and comprises providing N,N-diethyl-1,1,2,3,3,3-hexafluoropropylamine and tetrakis (dimethylamino) hafnium alternately and sequentially into the reaction chamber. In some embodiments, the process according to the current disclosure is a cyclic etching process, and comprises providing 1,1,2,2-tetrafluoro-N,N-dimethylethanamine and tetrakis (dimethylamino) hafnium alternately and sequentially into the reaction chamber. In some embodiments, the process according to the current disclosure is a cyclic etching process, and comprises providing 2,2-difluoro-1,3-dimethylimidazolidine and tetrakis (dimethylamino) hafnium alternately and sequentially into the reaction chamber.

In some embodiments, the process according to the current disclosure is a cyclic etching process, and comprises providing N,N-diethyl-1,1,2,3,3,3-hexafluoropropylamine and tetrakis (dimethylamino) zirconium alternately and sequentially into the reaction chamber. In some embodiments, the process according to the current disclosure is a cyclic etching process, and comprises providing 1,1,2,2-tetrafluoro-N,N-dimethylethanamine and tetrakis (dimethylamino) zirconium alternately and sequentially into the reaction chamber. In some embodiments, the process according to the current disclosure is a cyclic etching process, and comprises providing 2,2-difluoro-1,3-dimethylimidazolidine tetrakis (dimethylamino) zirconium alternately and sequentially into the reaction chamber.

and

The duration of providing the etchant (e.g., the halogenated silane etchant) into the reaction chamber (the etchant pulse time) may be, for example, from about 5 seconds to about 20 minutes. The duration of providing the etchant into the reaction chamber is selected based on the process, tool and other factors. In some embodiments, the duration of providing the etchant into the reaction chamber is from about 5 seconds to about 2 minutes, or from about 5 seconds to about 90 seconds, or from about 5 seconds to about 60 seconds. In some embodiments, the duration of providing the etchant into the reaction chamber is from about 15 seconds to about 5 minutes, or from about 15 seconds to about 3 minutes, or from about 15 seconds to about 2 minutes, or from about 10 seconds to about 90 seconds. In some embodiments, the duration of providing the etchant into the reaction chamber (the etchant pulse time) is may be longer than 5 seconds or longer than 10 seconds or longer than 30 seconds, or longer than 60 seconds. In some embodiments, the duration of providing the etchant into the reaction chamber (the etchant pulse time) may be shorter than about 15 minutes or shorter than about 10 minutes or shorter than about 5 minutes, or shorter than about 3 minutes, or shorter than about 60 seconds, or shorter than about 30 seconds.

Upon completion of the process step 130 (FIG. 1) the reaction chamber may be purged to remove any excess etchant and any reaction products. In some embodiments, the purge time after providing the etchant pulse may be from about 0.1 seconds to about 120 seconds, or from about 0.1 seconds to about 60 seconds, or from about 0.1 seconds to about 30 seconds, or from about 0.1 seconds to about 10 seconds, or from about 0.1 seconds to about 5 seconds, or from about 0.1 seconds to about 2 seconds, or from about 0.1 seconds to about 1 second, or from about 0.1 seconds to about 0.5 seconds. In some embodiments, the purge time after introducing the etchant is shorter than 60 seconds, shorter than 30 seconds, shorter than 10 seconds, shorter than 4 seconds, shorter than 1 seconds, or shorter than 0.5 seconds.

In some embodiments of the disclosure, the etch-priming reactant and the etchant are introduced into the reaction chamber alternately and sequentially. In some embodiments, the exemplary chemical etching process 100 of FIG. 1 comprises a cyclical chemical etching process comprising one or more repeated etch cycles, as denoted by the cyclical process loop 105 of FIG. 1. As illustrated in FIG. 1 the cyclical process loop 105 is shown as dashed line as the cyclical repetition of alternately and sequential introducing the etch-priming reactant (process step 120) and the vapor phase etchant (processes step 130) may be optional.

Therefore, in some embodiments, the exemplary process 100 (FIG. 1) comprises, performing a cyclical etch process comprising one or more repeated etch cycles. In some embodiments, a unit etch cycle (i.e., a single etch cycle) of the cyclical etch process can include, contacting a transition metal oxide layer with a vapor phase fluoroalkylamine thereby forming a fluorinated transition metal oxide surface (process step 120), and contacting the fluorinated transition metal oxide surface with a vapor phase halogenated silane etchant (process step 130).

In some embodiments of the disclosure, the cyclical chemical etch process may comprise an atomic layer etching process for etching a hafnium oxide zirconium oxide target layer. In such embodiments, the exemplary process 100 of FIG. 1 may comprise, performing an atomic layer etching process comprising a plurality of repeated etch cycles, wherein a unit etch cycle (e.g., a single etch cycle) of the atomic layer etching process comprises, contacting a surface of the hafnium zirconium oxide layer with a vapor phase fluorinating agent comprising a carbon atom boned to a nitrogen atom and at last one fluorine atom thereby forming a fluorinated hafnium zirconium oxide surface (process step 120), and contacting the fluorinated hafnium oxide surface with a vapor phase iodosilane etchant thereby etching no more than a monolayer of the hafnium zirconium oxide layer (process step 130).

Therefore, in some embodiments, the chemical etching processes according to the current disclosure are cyclical etch processes. Thus, in some embodiments, providing an etch-priming reactant (e.g., a haloalkylamine) and a vapor phase etchant (e.g., a iodosilane) into the reaction chamber are performed cyclically. In some embodiments, the reaction chamber is purged between providing a haloalkylamine and providing an etchant into the reaction chamber. In some embodiments, the cyclical etch process is performed in a plasma-free environment, i.e., without the introduction of reactive species generated from a plasma.

The chemical etching processes according to the current disclosure may be atomic layer etch (ALEt) processes. In ALEt processes thin layers of material are controllably removed using sequential reaction steps. In some embodiments, the sequential reaction steps are self-limiting. In contrast to conventional continuous etching, ALEt typically utilizes one or more etching cycles to remove material. In some embodiments, the chemical etching processes according to the current disclosure are self-limiting process. Thus, in an aspect, an atomic layer etching (ALEt) method of etching a target layer from a semiconductor substrate is disclosed herein. For example, an ALEt process may comprises providing a substrate comprising the target layer into a reaction chamber, contacting the target layer with a vapor phase fluorinated agent (e.g., a haloalkylamine), and contacting a modified surface of the target layer with vapor phase etchant (e.g., a iodosilane) in order to etch about a monolayer of the target layer from the substrate. In some embodiments, the ALEt processes of the present disclosure are performed in a plasma-free environment, i.e., without the introduction of reactive species generated from a plasma.

In some embodiments, the method is a self-limiting process. Thus, the etch-priming reactant may function, for example, by fluorinating substantially one layer of molecules on the target layer surface, thereby allowing for the removal of the fluorinated material from the target layer by subsequent contact with a vapor phase etchant (e.g., an iodosilane). Similarly, other modifications of the topmost molecular layers may be performed before providing the etchant into the reaction chamber, to provide for the self-limiting nature of an atomic layer etch process. Thus, in some embodiments, an etch-priming reactant is provided into the reaction chamber before providing a vapor phase etchant into the reaction chamber.

As disclosed herein, the exemplary chemical etching process 100 (FIG. 1) can comprise a cyclic etching process. In some embodiments a cyclical etch process is repeated at least once. In other words, providing an etch-priming reactant into the reaction chamber and providing etchant into the reaction chamber may be repeated at least once. Providing an etch-priming reactant into the reaction chamber and providing an etchant into the reaction chamber may be termed an etch cycle, i.e., a unit etch cycle or singular etch cycle. An etch cycle may further comprise purging the reaction chamber after providing an etch-priming reactant and/or after providing a vapor phase etchant into the reaction chamber. The number of etch cycles performed (i.e., the number of repeated unit etch cycles) can depend on the desired etch depth, and the etch rate of the process. The latter may be adjusted through process parameters, such as, the substrate temperature, for example.

In some embodiments, the cyclical etch process of FIG. 1 comprises at least 5 etch cycles. In some embodiments, the method comprises at least 10, or at least 50 etch cycles. In some embodiments, the method comprises at least 100 etch cycles. In some embodiments, the method comprises at least 200, or at least 300, or at least 500 etch cycles. In some embodiments, the method comprises from about 5 to about 500 etch cycles. In some embodiments, the method comprises from about 5 to about 100 etch cycles, such as from about 5 to about 50 etch cycles, or from about 10 to about 100 etch cycles, or from about 50 to about 100 etch cycles. In some embodiments, the method comprises from about 50 to about 500 etch cycles, such as from about 50 to about 200 etch cycles, or from about 100 to about 500 etch cycles. In some embodiments, the method comprises from about 200 to about 500 etch cycles.

An etch cycle may comprise a phase in which a substrate in a reaction chamber is contacted with a vapor-phase etch-priming reactant. In some embodiments, an etch cycle further comprises intermediate purging cycles after introducing the etch-priming reactant and after introducing the vapor phase etchant in order to remove any excess etch-priming reactant, vapor phase etchant, any reaction byproducts from the reaction chamber. In some embodiments this etch cycle can be repeated multiple times. In some embodiments an etch cycle is repeated multiple times sequentially. In some embodiments an etch cycle is repeated at intervals, for example at one, two or more intervals in another deposition process such as a deposition process.

In some embodiments, the target layer is etched at a rate from about 0.1 Å to about 5 Å per etch cycle, such as at a rate from about 0.1 Å to about 1.0 Å per etch cycle. In some embodiments, the target layer is etched at a rate from about 0.1 Å to about 0.5 Å per etch cycle, or at a rate from about 0.2 Å to about 0.5 Å per etch cycle. In some embodiments, the target layer is etched at a rate from about 0.1 Å to about 0.3 Å per etch cycle.

In some embodiments, the target layer may have an initial thickness (pre-etch) between 8 nm and 10 nm, or between 6 nm and 12 nm, or between 4 nm and 15 nm. In some embodiments, the target layer may have an initial thickness (pre-etch) of less than 20 nm, or less than 16 nm, or less than 12 nm, or less than 8 nm, or less than 4 nm, or between 4 nm and 20 nm.

In some embodiments of the disclosure, the cyclical etch process (e.g., cyclical process loop 105 of FIG. 1) may be repeated until a desired end criterion is reached as illustrated by the process step 140. Upon reaching the end criterion (process step 140) the cyclical etch cycle may be terminated and the exemplary chemical etching process of FIG. 1 may conclude, as illustrated by the process step 150.

In some embodiments, the end criterion (process step 140) may be based on performing a predetermined number of repetitions of the cyclical etch cycle, i.e., a known number of repetition of unit etch cycle. As a non-limiting, for a given set of process conditions, a unit etch cycle of exemplary process 100 may have a well-defined etch rate per cycle and therefore the number of etch cycles performed to remove a desired amount of the target layer can readily be determined.

In some embodiments, the end criterion (process step 140) may be based upon the amount of the target layer to be etched. As a non-limiting, the exemplary chemical etching process 100 may employ end point detection to determine when a predetermined amount of the target layer has been removed, at which point the cyclical etch process can be terminated.

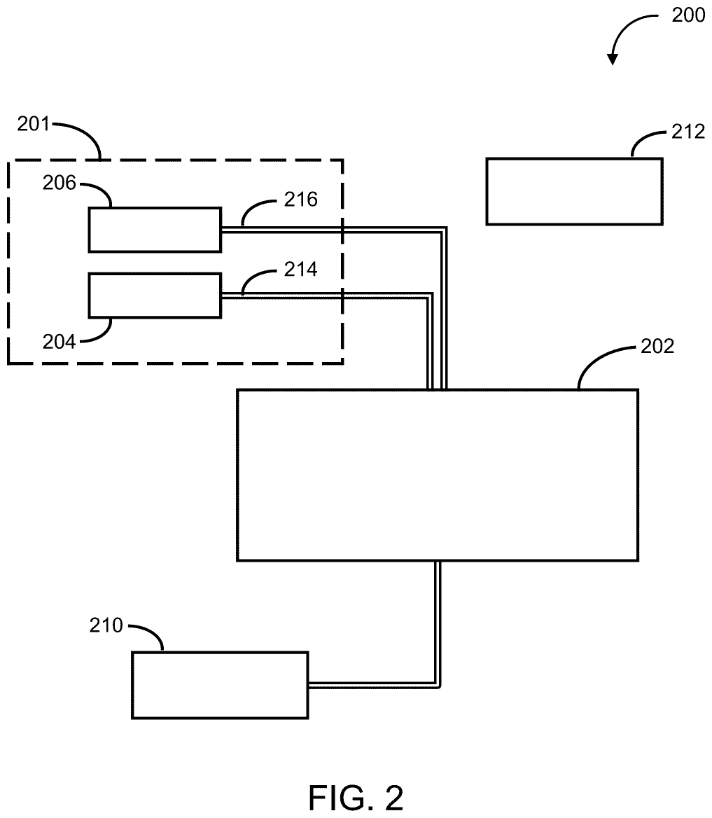

The embodiments of the present disclosure may also include apparatus for performing the chemical etching processes disclosure herein. For example, FIG. 2 illustrates a semiconductor processing apparatus 200 according to the current disclosure in a schematic manner. Semiconductor processing apparatus 200 can be used to perform the method as described

In the illustrated example, the semiconductor processing assembly 200 includes one or more reaction chambers 202, a reactant injector system 201, a haloalkylamine source vessel 204, an etchant source vessel 206, an exhaust source 210, and a controller 212. The semiconductor processing apparatus 200 may comprise one or more additional gas sources (not shown), such as an inert gas source, a carrier gas source and/or a purge gas source. Also, in cases where materials are deposited in the same reaction chamber, the semiconductor processing apparatus 200 may further comprise additional precursor and/or reactant vessels.

Reaction chamber 202 can include any suitable reaction chamber. In some embodiments, the reaction chamber is constructed and arranged to perform a cyclical etch process, such as a cyclical chemical vapor etch process and/or an atomic layer etch process. In some embodiments, the reaction chamber 202 may be a vapor deposition chamber, such as an atomic layer deposition (ALD) reaction chamber or a chemical vapor deposition (CVD) reaction chamber.

The haloalkylamine source vessel 204 can include a vessel and a haloalkylamine as described herein—alone or mixed with one or more carrier (e.g., inert) gases. An etchant source vessel 206 can include a vessel and an etchant as described herein—alone or mixed with one or more carrier gases. Although illustrated with two source vessels 204 and 206, semiconductor processing apparatus 200 can include any suitable number of source vessels. Source vessels 204 and 206 can be coupled to reaction chamber 202 via lines 214 and 216, which can each include flow controllers, valves, heaters, and the like. In some embodiments, the haloalkylamine in the haloalkylamine source vessel 204 and/or the etchant in the etchant source vessel 206 may be heated.

Exhaust source 210 can include one or more vacuum pumps.

Controller 212 includes electronic circuitry and software to selectively operate valves, manifolds, heaters, pumps and other components included in the semiconductor processing apparatus 200. Such circuitry and components operate to introduce reactants, reactants and purge gases from the respective sources. Controller 212 can control timing of gas pulse sequences, temperature of the substrate and/or reaction chamber 202, pressure within the reaction chamber 202, and various other operations to provide proper operation of the semiconductor processing apparatus 200. Controller 212 can include control software to electrically or pneumatically control valves to control flow of reactants, reactants and purge gases into and out of the reaction chamber 202. Controller 212 can include modules such as a software or hardware component, which performs certain tasks. A module may be configured to reside on the addressable storage medium of the control system and be configured to execute one or more processes.

Other configurations of the semiconductor processing apparatus 200 are possible, including different numbers and kinds of reactants and reactant sources. Further, it will be appreciated that there are many arrangements of valves, conduits, reactant sources, and auxiliary reactant sources that may be used to accomplish the goal of selectively and in coordinated manner feeding gases into reaction chamber 202. Further, as a schematic representation of a semiconductor processing apparatus, many components have been omitted for simplicity of illustration, and such components may include, for example, various valves, manifolds, purifiers, heaters, containers, vents, and/or bypasses.

During operation of semiconductor processing apparatus 200, substrates, such as semiconductor wafers (not illustrated) including one or more target layers, are transferred from, e.g., a substrate handling system to reaction chamber 202. Once substrate(s) are transferred to reaction chamber 202, one or more gases from gas sources, such as reactants, etchants, reducing agents, carrier gases, and/or purge gases, are introduced into reaction chamber 202.

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation

What is claimed is:

1. A method for chemically etching a target layer, the method comprising:
seating a substrate comprising a target layer in a reaction chamber; and
contacting a surface of the target layer with an etch-priming reactant comprising a haloalkylamine thereby forming a modified surface; and
contacting the modified surface with an etchant comprising a halogenated silane thereby etching a portion of the target layer.

2. The method of claim 1, wherein the target layer comprises a transition metal oxide.

3. The method of claim 2, wherein the transition metal oxide comprises a ternary transition metal oxide.

4. The method of claim 3, wherein the ternary transition metal oxide comprises a hafnium zirconium oxide.

5. The method of claim 1, wherein the etch-priming reactant and the etchant are introduced into the reaction chamber alternately and sequentially.

6. The method of claim 1, wherein the haloalkylamine comprises a carbon atom bonded to a nitrogen atom and to at least one fluorine atom.

7. The method of claim 1, wherein the haloalkylamine is selected from the group consisting of 2,2-difluoro-1,3-dimethylimidazolidine, N,N-diethyl-1,1,2,3,3,3-hexafluoro-1-propanamine, and 1,1,2,2,-tetrafluoroethyl-N,N-dimethylamine.

8. The method of claim 1, wherein the halogenated silane comprises an iodosilane selected from the group consisting of iodosilane (H₃Sil), diiodosilane (H₂Sil₂), tetraiododisilane (H₂Si₂I₄), and triiodosilane (HSil₃).

9. The method of claim 8, wherein the halogenated silane comprises tetraiododisilane (H₂Si₂I₄).

10. The method of claim 1, further comprising heating the substrate to a temperature of less than 400° C.

11. A method for chemically etching a transition metal target layer, the method comprising:
seating a substrate comprising a transition metal oxide target layer in a reaction chamber; and
performing a cyclical etch process comprising one or more repeated etch cycles, wherein a unit etch cycle of the cyclical etch process comprises;
contacting the transition metal oxide target layer with a vapor phase fluoroalkylamine thereby forming a fluorinated transition metal oxide surface; and
contacting the fluorinated transition metal oxide surface with a vapor phase halogenated silane etchant.

12. The method of claim 11, wherein the vapor phase fluoroalkylamine is selected from the group consisting of 2,2-difluoro-1,3-dimethylimidazolidine, N,N-diethyl-1,1,2,3,3,3-hexafluoro-1-propanamine, and 1,1,2,2,-tetrafluoroethyl-N,N-dimethylamine.

13. The method of claim 11, wherein the vapor phase halogenated silane etchant comprises diiodosilane.

14. The method of claim 11, wherein the transition metal oxide target layer comprises a hafnium zirconium oxide layer.

15. The method of claim 14, wherein the hafnium zirconium oxide layer is crystalline.

16. The method of claim 11, wherein the cyclical etch process is performed in a plasma-free environment.

17. A method for atomic layer etching a hafnium zirconium oxide layer, the method comprising:
seating a substrate comprising a hafnium zirconium oxide layer into a reaction chamber; and
performing an atomic layer etching process comprising a plurality of repeated etch cycles, wherein a unit etch cycle of the atomic layer etching process comprises;
contacting a surface of the hafnium zirconium oxide layer with a vapor phase fluorinating agent comprising a carbon atom bonded to a nitrogen atom and to at least one fluorine atom thereby forming a fluorinated hafnium zirconium oxide surface; and
contacting the fluorinated hafnium zirconium oxide surface with a vapor phase iodosilane etchant thereby etching no more than a monolayer of the hafnium zirconium oxide layer.

18. The method of claim 17, wherein the atomic layer etching process is performed in a plasma-free environment.

19. An apparatus for performing the method of claim 17.

20. A method for chemically etching a target layer, the method comprising
seating a substrate comprising a target layer in a reaction chamber; and
contacting a surface of the target layer with an etch-priming reactant comprising a haloalkylamine thereby forming a modified surface, and
contacting the modified surface with an etchant comprising a metalorganic compound having a group 4 metal bonded to an alkylamine group thereby etching a portion of the target layer.
